(19) United States
(12) Patent Application Publication
(10) Pub. No.: US 2015/0325649 A1
(43) Pub. Date: Nov. 12, 2015

(54) Nanowires and Methods of Forming

(71) Applicant: Brookhaven Science Associates, LLC, Upton, NY (US)

(72) Inventors: Mingzhao Liu, Hauppauge, NY (US); Chang-Yong Nam, Stony Brook, NY (US)

(21) Appl. No.: 14/708,961

(22) Filed: May 11, 2015

Related U.S. Application Data
(60) Provisional application No. 61/991,265, filed on May 9, 2014.

(51) Int. Cl. H01L 29/06; H01L 29/12; H01L 21/02

(52) U.S. Cl. CPC H01L 29/0676; H01L 21/02422; H01L 21/02381; H01L 21/02491; H01L 21/02631; H01L 21/02499; H01L 21/02513; H01L 21/02535; H01L 21/02524; H01L 21/02538; H01L 21/02603; H01L 21/0262; H01L 29/125

(57) ABSTRACT

An array of out-of-plane, nanowires may be formed spontaneously when a material is deposited over a freshly sputter-deposited porous film under high vacuum. The nanowires may be formed without an apparent catalyst. It is the nanoporous structure of the sputter-deposited porous film that confines the size of permeated material domains during its vapor deposition, which may cause a certain surface-to-volume ratio and subsequent melting point reduction, rendering the domains of the material molten or partially molten at room temperature. The release of surface energy provides a force for the domains to diffuse and to eventually erupt from the porous thin film and may form nanowires. Due to the universality of higher surface energy for nanoparticles, the present nanowires may be applicable for scalable growth of one-dimensional nanostructures of various other materials with moderate melting points. Furthermore, the absence of a catalyst in this method may eliminate the unwanted but inevitable diffusion of catalyst atoms into the nanostructures, thus allowing a route for the growth of nanostructure of higher purity and better controlled properties.

This application claims the benefit of U.S. Provisional Application No. 61/991,265, filed on May 9, 2014, the specification of which is incorporated by reference herein in its entirety for all purposes.

The present application was made with government support under contract number DE-AC02-98CH 10886 and DE-SC0012704 awarded by the U.S. Department of Energy. The United States government has certain rights in the invention(s).

### FIELD OF THE INVENTION

This application relates to metallic nanowires and methods of making the same. In particular, the application relates to forming arrays of nanowires comprising a semimetal.

### BACKGROUND

Bismuth (Bi) is a semimetal when crystallized in a rhombohedral lattice. It has a small indirect band overlap and a highly anisotropic Fermi surface. Bismuth possesses intriguing electronic properties. For example, significant quantum confinement can be observed in bismuth nanostructures, which turns the semimetal into a narrow band gap semiconductor.

Advances in material processing techniques have resulted in the fabrication of other novel nanostructures, such as arrays of nanowires. Arrays of nanowires are a type of nanostructure with quasi-one dimensional characteristics and they provide an alternative means to study the intricate physics as well as the practical applications of nanostructured materials.

The constituent materials in many magnetic nano structures include transition metals, alloys, and noble metal elements. Bismuth has been used to study both classical and quantum finite size effects, for which the characteristic lengths are the carrier mean free path and Fermi wavelength, respectively. The pursuit of quantum size effects since the 1960's, initiated by the observation of resistivity oscillations in Bi thin films as the thickness is varied, has continued to be of interest. Most of these studies involve Bi thin films, for which film thickness is a variable. However, fabrication of high quality Bi thin films utilizing prior art vapor deposition remains technically challenging. The properties of Bi thin films fabricated by vapor deposition may be sensitive to the purity and the concentration of crystal defects, which are further compounded by the low melting point of Bi.

### SUMMARY

In some examples, methods for forming nanowires comprising a semimetal are described. The method may comprise supplying a substrate having a first surface, depositing a thin film onto the first surface of the substrate, supplying under vacuum a vapour form of the semimetal onto the thin film, and continuously supplying the vapour until nanowires of the semimetal are formed. The nanowires grown by this method may form a nanoarray that extends orthogonally to the thin film. The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1.a illustrates an experimental apparatus for PVD of elemental vanadium and bismuth through magnetron sputtering and thermal evaporation,

FIG. 1.b shows a SEM image of the out-of-plane bismuth nanowires on a substrate during deposition,

FIG. 1.c shows a XRD pattern recorded from the nanowire-covered substrate in 1.b,

FIG. 1.d shows longer and thinner individual nanowires and thicker array of nanowires covering the substrate when the substrate is heated to 50° C., and

FIG. 1.e illustrates bismuth deposits as a flat but grainy film over porous film of vanadium when the substrate is cooled to 0° C.;

FIG. 2.a shows a TEM image and in the inset shows a SAED pattern of a Bi nanowire that grows along [10 1̅0] direction;

FIG. 2.b shows a TEM image and in the inset shows a SAED pattern of a Bi nanowire that grows along [10 1̅2̅] direction;

FIG. 2.c shows a dark field scanning TEM image at atomic resolution of the single crystallinity of a Bi nanowire growing along [10 1̅2̅] direction where the inset indicates the area selected from the nanowire for high resolution imaging;

FIG. 3.a shows a SEM image of a freshly deposited porous film of vanadium over a silicon substrate, featuring a surface roughness of about 3 to 4 nm;

FIG. 3.b shows a top-view TEM image of a porous film of vanadium deposited over a suspended SiO₂ window;

FIG. 3.c shows a plot of X-ray reflectivity R versus the momentum transfer vector Q, where the critical moment Q_{c} is denoted by an arrow and a dashed vertical line indicates the expected critical moment Q_{c,bulk} for a vanadium film at its bulk density (6.0 g/cm³);

FIG. 4.a shows a cross-sectional TEM image on the left side of an as-deposited bismuth nanowire over a growth substrate, and shows an EDX mapping on the right side;

FIG. 4.b shows a HAADF image left panel) of the continuous thin film and corresponding EDX mapping (right panel);

FIG. 5 shows a series of schematics illustrating the growth of bismuth nanowires starting from the columnar porous film of vanadium on a substrate at 5.a, the porous film being infiltrated by Bi deposition and the release of surface tension propelling Bi from the porous film at 5.b, forming a larger crystalline domain that serves as a nucleation center for further growth, at 5.c, and with continuous repetition of the Bi deposition and extrusion leading to the growth of out-of-plane Bi nanowire at 5.d;

FIG. 6.a through FIG. 6.f show a high resolution SEM study over time as follows—in FIG. 6.a for 0 s, FIG. 6.b for 4 s, FIG. 6.c for 8 s, FIG. 6.d for 12 s, FIG. 6.e for 14 s, and FIG. 6.f for 20 s of Bi nanowires growing in situ from as deposited V/Bi film where the arrows indicate the position of a nanowire growing continuously from a random spot on the film such that more nanowires start to erupt from the area under electron beam scanning;

FIG. 7.a shows a TEM image of a typical bismuth nanowire, and FIG. 7.b shows an EDX spectrum of a typical bismuth nanowire;

FIG. 8 shows a top view SEM image of as-grown bismuth nanowires, taken from a sample in FIG. 1.b;

FIG. 9 shows a SEM image taken at a vertical cross section of a substrate, showing the edge of the bismuth film deposited without vanadium;

FIGS. 10.a and 10.b show a TEM of bismuth nanowires with growth orientations respectively along (1 1̅0 4̅) direction in FIG. 10.a and (1 1̅0 1̅) direction in FIG. 10.b, where the insets respectively show the corresponding electron diffraction patterns;

FIG. 11.a shows a schematic of the formation of Kiessig fringe due to the interference between X-ray beams reflected from the top and bottom surfaces of a thin film (n₂) deposited on a substrate n₃,

FIG. 11.b shows a plot of X-ray reflectivity from a vanadium film against n₂ sin q₂, showing uniform spacing for the fringe;

FIG. 12 depicts an illustration of a columnar structure of sputter-deposited vanadium film as a honeycomb array of hexagonal pillars of vanadium, each with height L and side width a; and

FIG. 13 shows a phase diagram of bulk bismuth showing the liquid phase labeled “Liquid” and solid phases in portions labeled I-VIII which include the rhombohedral phase (I) and several high-pressure phases, and the lowest melting point of bismuth (labeled by an arrow) corresponds to the triple point between the liquid phase, solid phase II, and solid phase III;

all arranged according to at least some embodiments described herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

It will be understood that any compound, material or substance which is expressly or implicitly disclosed in the specification and/or recited in a claim as belonging to a group or structurally, compositionally and/or functionally related compounds, materials or substances, includes individual representatives of the group and all combinations thereof.

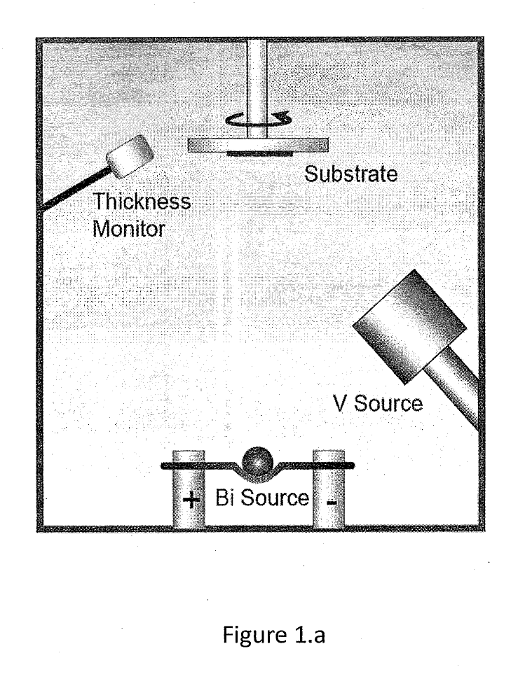

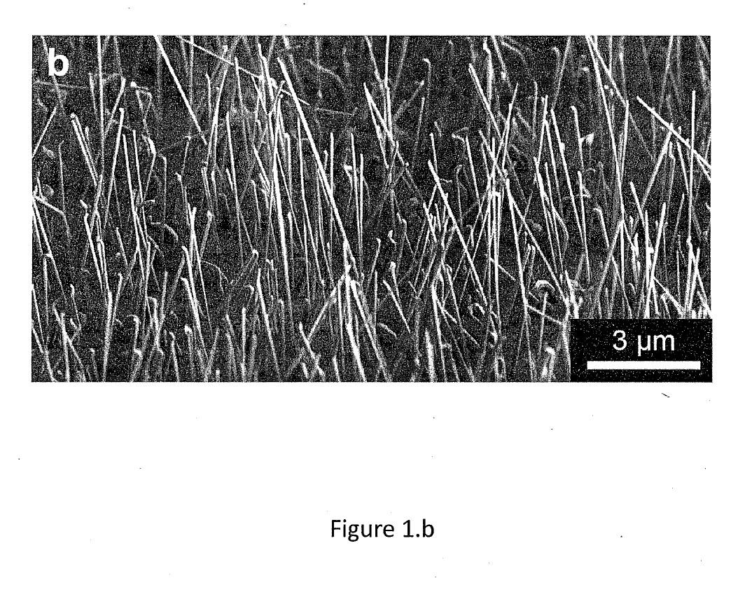

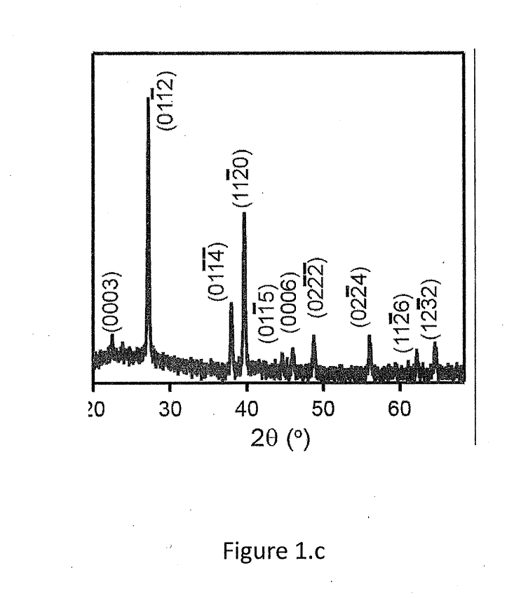

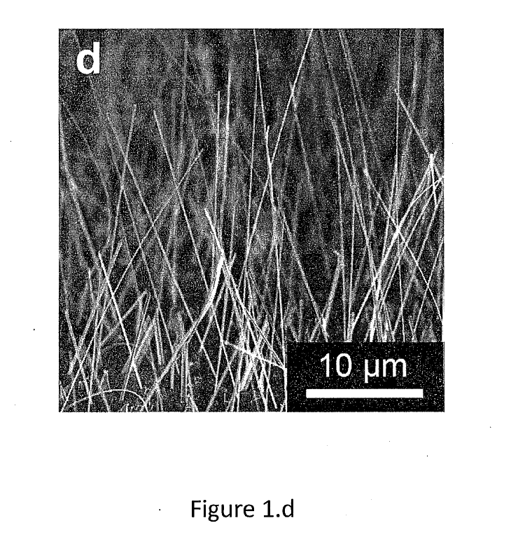

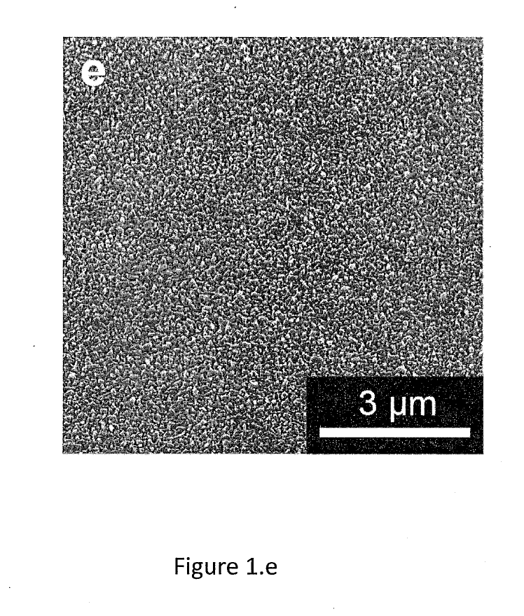

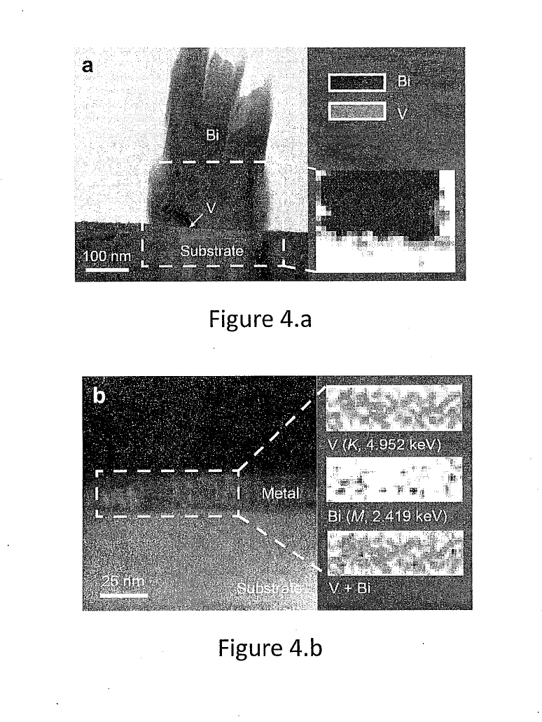

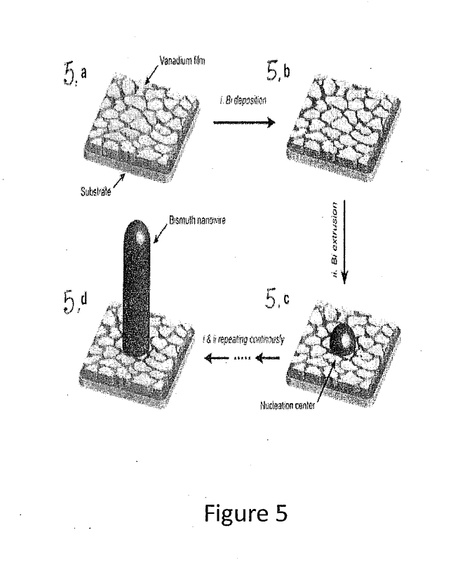

FIG. 1.a illustrates an example apparatus for fabricating the present nanowires. In an embodiment, an array of single crystalline nanowires may be formed during a thermal evaporation of bismuth, over a porous thin film at room temperature. The nanowires may be formed spontaneously and with high yield, for example greater than about 30%, 35%, 40%, 45% 50%, 55%, 60%, 65% or 70% of the bismuth deposited on the substrate may be converted to nanowires. The nanowires may have a smooth surface and, depending on the temperature of formation, they may have diameters of between about 90-120 nm, and lengths of about 6-8 microns. The formed nanowires may be pure bismuth that does not alloy with the porous thin film. The bismuth nanowires may stand on or be supported at their base by the porous film (for example a vanadium thin film) with a clean interface and in the absence or substantial absence of sprout-like structures (FIG. 4(a)). The bismuth nanowires may have a high aspect ratio such as for example greater than about 40, 45, 50 or 55, or between about 40 to a maximum of about 100, or between about 40 to a maximum of about 90. The present nanowires may form an array. After the growth of the nanowires, the surface of the nanowires may be functionalized, or they may be selectively functionalized. Functionalization of the nanowire, may be carried out with the substrate taken out of the vacuum.

The surface states of bismuth collectively act as a two dimensional metal with high electron mobility which is in contrast to the bulk three dimensional metal. The surface states of bismuth act differently from their bulk counterparts and may be considered as quasi-two-dimensional metals, which may contribute to the development of reduced dimensional structures. As such, the present bismuth nanowires, arrays and thin films, and the methods for making them may be useful in electronic, optoelectronic, and thermoelectric applications.

In an embodiment, a template-free method is disclosed for growing nanowires. The nanowires may be in an array. The present technique utilizes a substrate that is about 0.3 to 2.0 mm thick. The substrate may be glass, silicon or other similar type of materials known in the art for use as a substrate. The substrate can be any shape and can have a surface that is flat or the surface can have some curvature or roughness. The size of the substrate may be any size such as for example, 15×15 mm² to as large as a 5×5 inch squared square. The substrate may be maintained at room temperature or cooler than room temperature. The substrate has a first surface onto which the porous film may be coated. The first surface of the substrate may be flat.

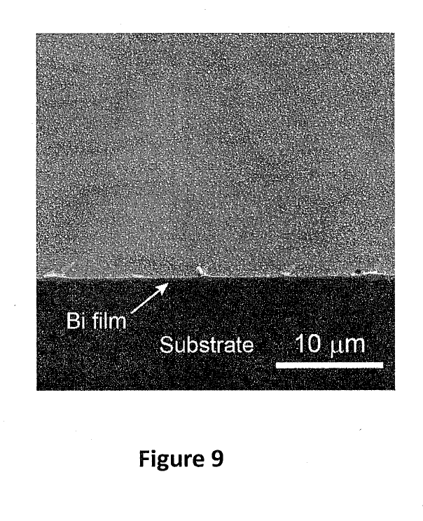

The thin film is deposited onto the first surface of the substrate. The thin film may be a porous film. The porous film coating may be a thin film about 20-100 nm, 20-80 nm, 20-60 nm, or 20-40 nm thick. The porous film may be made of for example, vanadium, titanium, niobium, or tantalum. The porous thin film may be continuous. The porous film may be freshly deposited onto the first surface of the substrate that is maintained at room temperature. The porous film (of for example, vanadium) may be sputter-deposited. The porous film once deposited on the first surface of the substrate may have small pores for example about 1 to 2 nm (porosity of for example about 22%) and a surface roughness the size of about 3 nm roughness. The porous film may have a vertical cross section that is porous and may have a columnar structure. The columnar structure of the porous film may form the site of a nucleation center that supports nanowire growth. When a vapor material such as for example bismuth is deposited over the porous film, freshly deposited through thermal evaporation, it may form an array of single crystalline bismuth nanowires extending orthogonally to the porous film. An exemplary deposition apparatus is illustrated in FIG. 1.a. If the deposition of the porous film (of for example vanadium) is omitted, a material like bismuth may deposit as a grainy but continuous thin film despite an otherwise comparable deposition condition (see FIG. 9). The forest of out-of-plan nanowires may be matte grayish in appearance rather than mirror-like that is more typically expected from thermal evaporation of metal

High resolution electron microscopy studies indicate that the vanadium thin film may be mildly porous, and that bismuth infiltrates the pores of the thin film, foaming approximately 1-nm sized embedded domains during its deposition. Without being bound to any particular theory it may be that the nanowire growth is induced by a large surface energy of the bismuth domains, which reduces their local melting point and drives them out of the vanadium matrix to release the surface tension and to form nanowires similar in fashion to extruding. Evidence for the present mechanism is provided by in situ high resolution scanning electron microscopy studies, where a subtle localized heating controlled by electron beam irradiation demonstrates the promotion of nanowire growth from the residual bismuth trapped in the trenches of the porous vanadium film.

In an embodiment, a substrate and its first surface are cleaned in oxygen plasma before being introduced into a physical vapor deposition (PVD) chamber. The PVD chamber is pumped to a base pressure below 10⁻⁶ Torr. A porous film may be deposited by DC magnetron sputtering under argon plasma to achieve a nominal thickness of between about 20 to about 100 nm, 20 to 80 nm, 20 to 60 nm, or 20 to 40 nm on the first surface, at a deposition rate of about 0.03 nm/s. Immediately after the deposition of for example, the porous vanadium film the PVD chamber may be returned to its base pressure and, bismuth may be deposited over the vanadium coated substrate by thermal evaporation to a thickness of about 50 nm, at a deposition rate of about 0.1 to about 0.2 nm/s. Thicknesses of vanadium and bismuth layers may be monitored in situ with a calibrated quartz crystal microbalance. The substrate temperature may be maintained at a desired room temperature during the course of the depositions using a Peltier cooler/heater in contact with the back of the substrate.

### Interface Between Porous Film and Material in Vapor Form

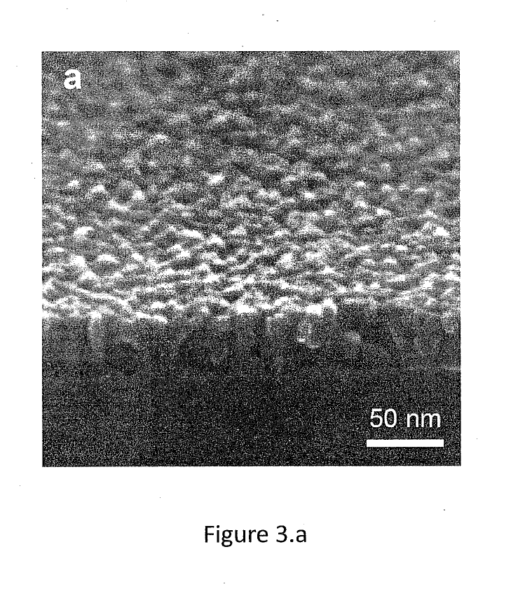

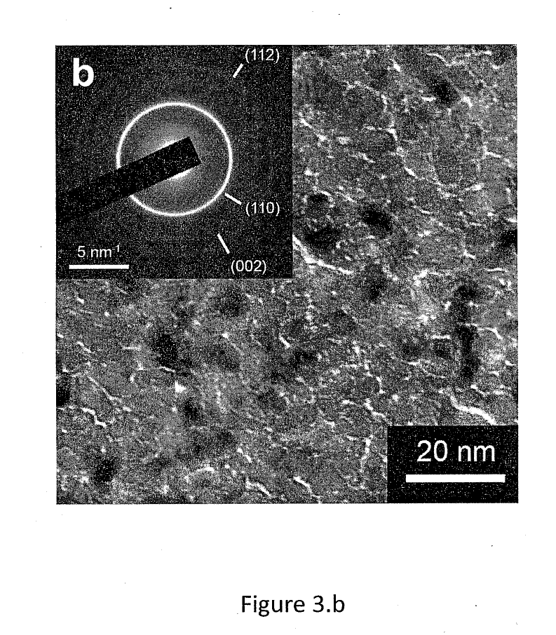

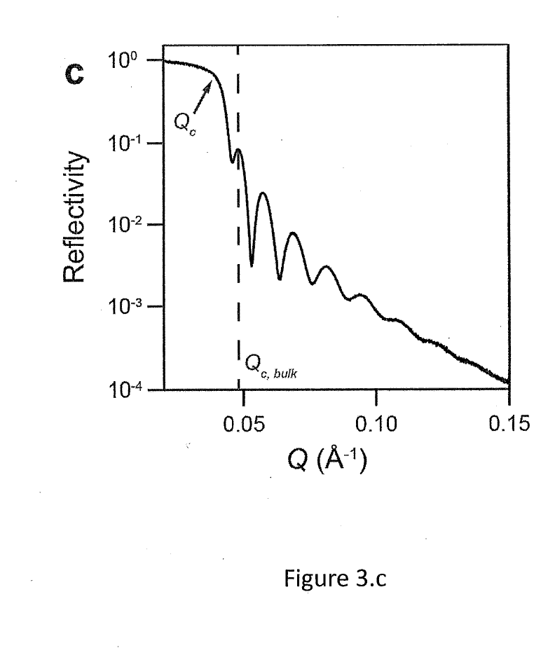

The sputter-deposited porous film (for example, the vanadium thin film) appears flat but grainy under SEM, featuring a surface roughness of between about 3-4 nm, while its vertical cross section indicates a porous and columnar structure (FIG. 3.a). In a top-view TEM image of a vanadium porous film deposited over a suspended SiO₂ window, the vertical columns appear as individual discrete islands separated by about 1 nm wide trenches, with the diameters 8-9 nm and the packing density 1.5-1.6×10⁴ μm⁻² (FIG. 3(b)). The SAED image supports that the vanadium grains crystallize in bulk bcc lattice with no preferred orientation. The formation of a porous thin film is not uncommon during magnetron sputtering against a cold substrate, as the deposited atoms quickly lose kinetic energy before forming a closely packed structure. According to the zone model by Thornton J A. Influence of apparatus geometry and deposition conditions on structure and topography of thick sputtered coatings. J. Vac. Sci. Technol. 1974, 11(4): 666-670, the sputter deposition of vanadium over a substrate at room temperature should form a columnar structure with voids between grain boundaries due to its high melting point (2183 K). The porosity of the vanadium film is quantitatively assessed through its X-ray reflectivity, which gives a direct measurement of the electron density profile in a thin film.

In FIG. 3.c the reflectivity is plotted against the momentum transfer vector

Q=4π sin θ/λ Eq#1

where θ is the incident angle and λ=1.54 Å, the X-ray wavelength. The electron density ρₑ in the vanadium film is determined by the critical momentum Q_{c}, a value marked by the sudden decrease of reflectivity from near unity, through the relation

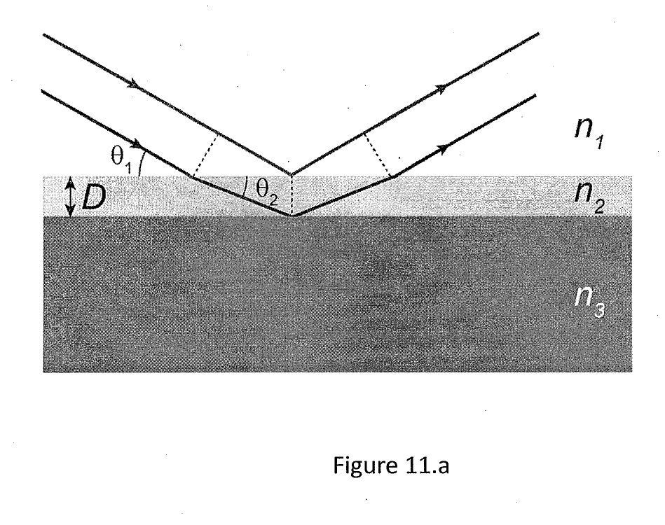

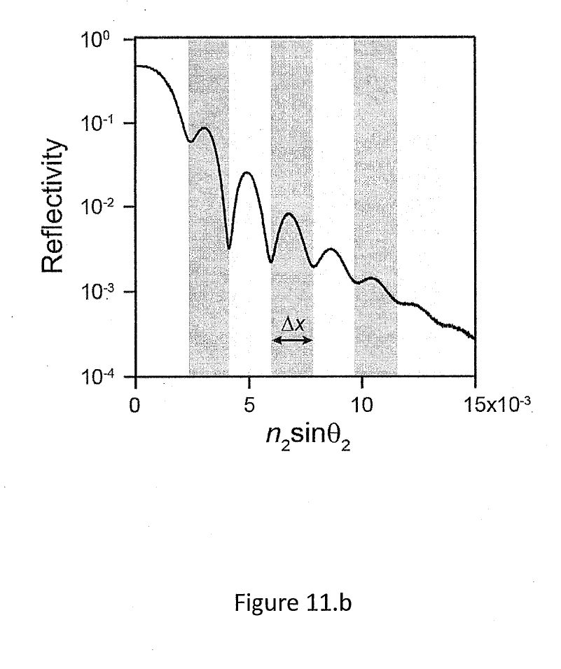

Qᵣ²=16πrₛρₑ Eq #2

in which rₑ=2.818×10⁻⁵ Å, the classical electron radius. ρₑ=1.27 Å⁻³ is obtained based on the observed Q_{c} at 0.042 Å⁻¹, which is 78% of the electron density of bulk vanadium (1.63 Å³), thus suggesting a porosity of 22% for the film. If the vanadium film reaches its bulk density, the critical momentum Q_{c} would be 0.048 Å⁻¹. Due to the interference between beams reflected from the top and bottom surfaces of the porous vanadium film, Kiessig fringes appear at higher Q and are consistent with the film thickness (D) of 40 nm (FIG. 11).

Cross-sectional TEM studies show that in the case of bismuth, atoms infiltrate or diffuse into the trenches between vanadium columns during the bismuth deposition. Infiltration may be either directly or as adatoms through surface diffusion, before forming condensed domains, which may become nucleation centers for nanowire growth. Thus, the pores may become the site for nucleation centers. The specimen in the TEM study is a 40-nm-thick cross-sectional slice of the bismuth/vanadium film mounted on a copper grid for the TEM using the focused ion beam milling and lift-out technique. At lower resolution (FIG. 4.a, left panel) the lateral structure of the thin film is revealed, showing a continuous film over the substrate and a bismuth nanowire on top (only the base portion of nanowires remains in the slice). Through the EDX mapping it can be confirmed that the nanowire is substantially pure bismuth (dark grey/top of the right panel in FIG. 4.a) and that the continuous film is mostly vanadium (light grey/bottom of the right panel in FIG. 4.a). As used herein substantially pure bismuth may be at least about 99%, at least about 95% or at least about 90% in purity. Within the detection limit of the EDX analysis (about 1%) vanadium is not found. At higher resolution, a high-angle annular dark-field (HAADF) image, which is highly sensitive to Z-contrast, shows brightness variation across the continuous thin film (FIG. 4.b, left panel), suggesting the incorporation of bismuth (Z=83) atoms into the vanadium (Z=23) film. EDX mapping at higher resolution locates scattered bismuth islands (FIG. 4.b, right panel) that correlate with the bright spot in the HAADF image. On the other hand, observations are not found of a continuous bismuth layer on top of the vanadium-rich porous film layer and reveal the inclusion of nanometer-sized bismuth domains into the vanadium thin film. This would be consistent with the high yield of the bismuth nanowire formation.

The formation of nanowires may also depend on the substrate temperature, and therefore it may be a thermally activated process. By using a Peltier substrate cooling/heating stage, the substrate may be maintained at room temperature (295 K) during deposition of the porous film. It may be set to between 273 K and 323 K during the bismuth deposition.

The higher substrate temperature may be found to increase the diameter and length of bismuth nanowires respectively up to ˜200 nm and 20-30 μm, at 323 K, and ˜400 nm and over 100 μm at 348 K. When the substrate is cooled to 285 K, thinner (60-80 nm) and shorter (0.5-1 μm nanowires may be formed. When the substrate is cooled to 273 K, however, no nanowire growth is observed. Only a continuous film (FIG. 1.d) can be observed.

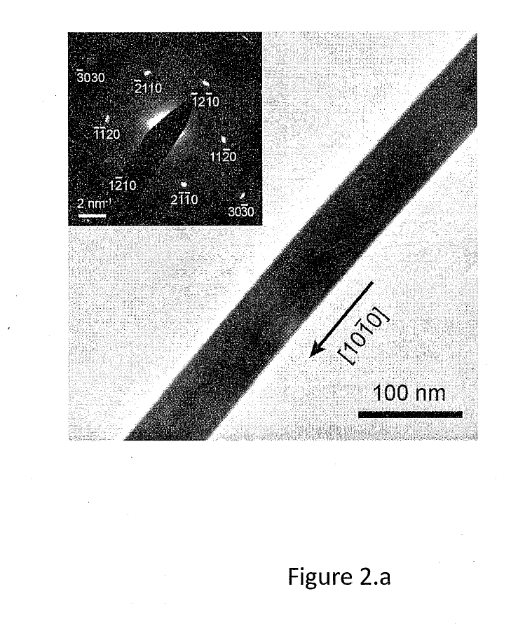

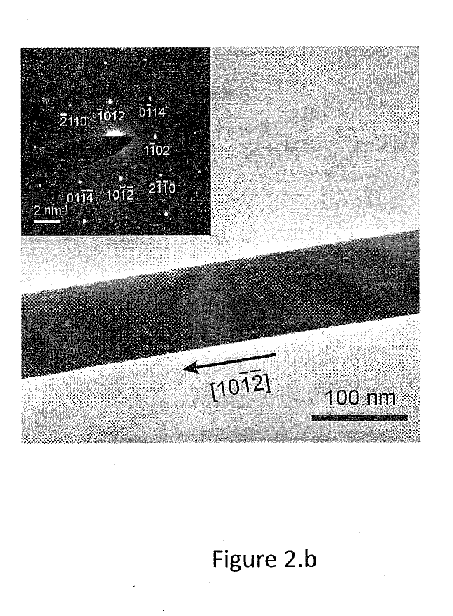

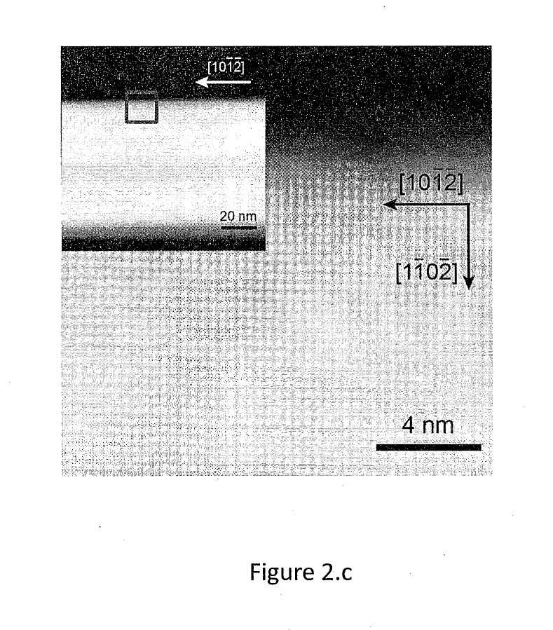

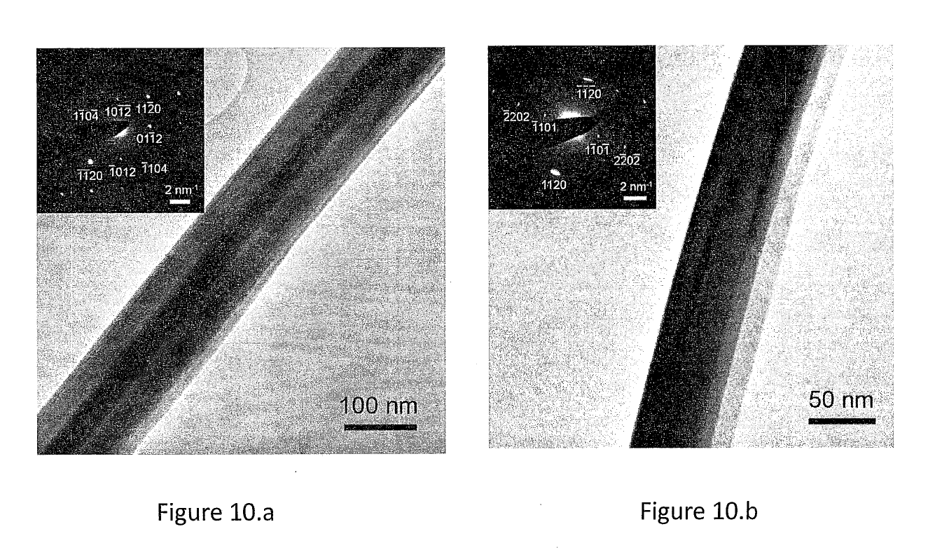

High resolution transmission electron microscopy (TEM) studies confirm that the bismuth nanowires are mostly single crystalline and have smooth surfaces. In FIG. 2.a a dark-field scanning TEM image is presented of a Bi nanowire that extends along the direction of [10 1̅2̅]. At higher magnification a nearly square lattice may be seen, as the [1 1̅02] and [10 1̅2̅] directions can be respectively indexed as [100] and [010] in the pseudocubic notation for rhombohedral bismuth. Further survey of the bismuth nanowires through TEM and selective area electron diffraction (SAED) indicates that the most frequent growth directions are [1 1̅02] and [1 2̅10] (FIGS. 2.b and 2.c), while less frequent directions, are also found in FIG. 10.

### Growth Mechanism

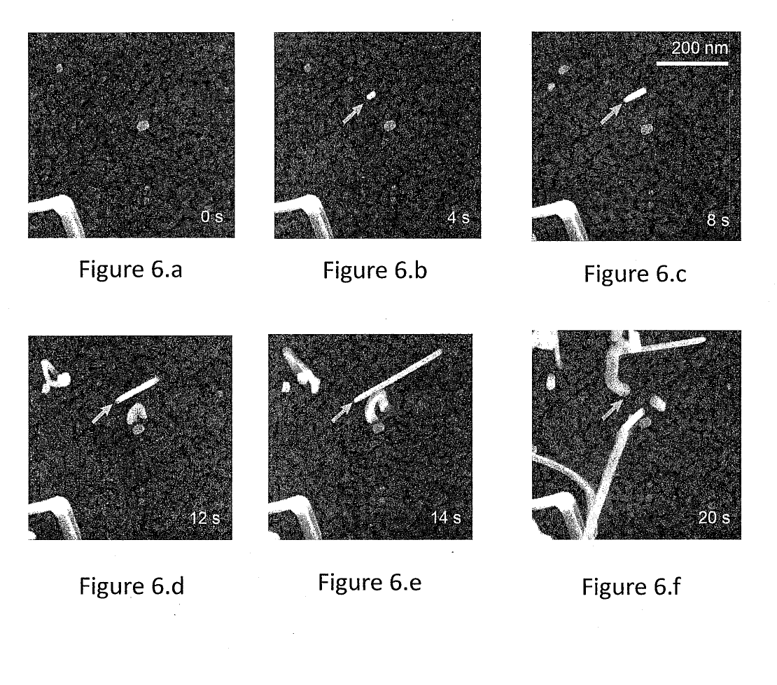

A present mechanism for the nanowire formation is illustrated in FIG. 5. In the present mechanism, bismuth vapor being deposited may infiltrate into the trenches between the vanadium columns of the porous film. The bismuth may condense in the trenches with a very large surface-to-volume ratio. Driven by excess surface energy, dispersed bismuth may be expelled from the trenches and agglomerate into a larger domain that serves as a nucleation center for future growth. The act of expelling the dispersed bismuth may take place immediately. During the deposition of bismuth, the condensation and expelling may repeat continuously, which eventually may result in the formation of the out-of-plane bismuth nanowires with the growth front at the root of a nanowire. The present mechanism may allow nanowire growth for as long as there is a continuous flow and supply of bismuth. This may produce nanowires of 20 μm or more in length. This process takes advantage of the high surface energy of bismuth (0.55 N/m in solid state and 0.38 N/m in liquid state), which may lead to reduction in the melting point for the highly dispersed bismuth. In general, the melting point Tₘ of a small particle is related to its bulk melting point T₀ through

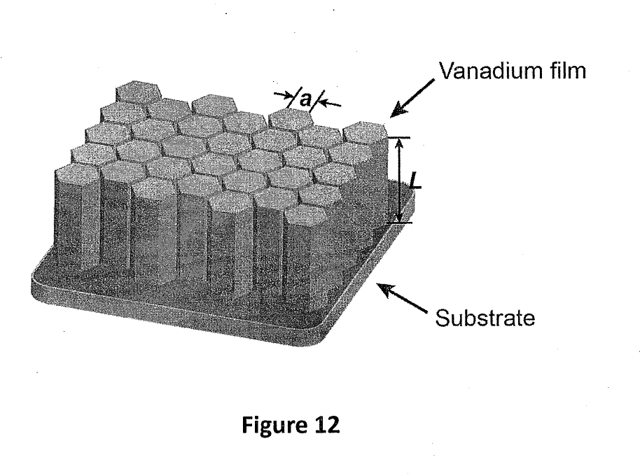

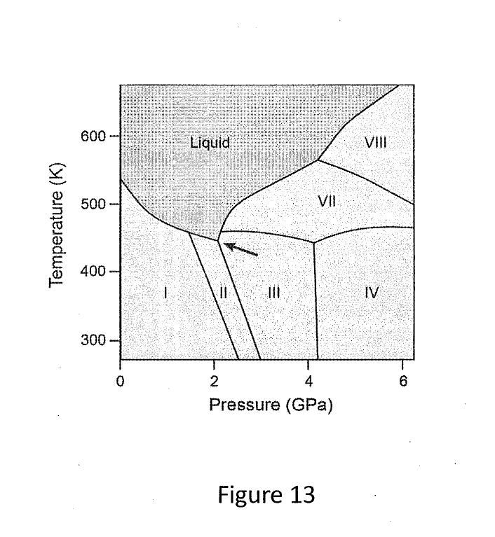

Tₘ/T₀=1−ηS/V, Eq. #3

where S and V are respectively the surface area and volume of the particle. For bismuth the coefficient η has been obtained experimentally as 0.23 nm. For the bismuth dispersed in the trenches an average surface to volume ratio S/V=1.9 nm⁻¹ may be estimated (FIG. 12), which subsequently gives an average local melting point Tₘ=306 K, only ˜56% of Tₒ. The low local melting point indicates that the bismuth deposited into the vanadium trenches is close to being molten at room temperature. Thus, the bismuth may be highly mobile and may be capable of migrating into larger crystal domains and eventually form the nanowires, following the present mechanism. It is noted that mechanical stress may be known to be able to lower the melting point of bismuth (˜0.06 K per 1 MPa pressure) since bismuth has a denser liquid phase. However, as the rhombohedral bismuth transforms to denser solid phases at higher pressure, the melting point may not be reduced indefinitely by stress. According to its phase diagram, bismuth reaches the lowest melting point of 443 K at 2.13 GPa, while even higher pressure increases melting point instead (FIG. 13). The phase diagram is reconstructed based on the work of Bundy F P. Phase diagram of bismuth to 130 000 kg/cm², 500° C. Phys Rev 1958, 110(2): 314-318. It is therefore believed that the nanowire growth at room temperature is related to surface energy, and not related to stress.

The surface-energy-driven growth mechanism is further supported by the temperature dependent trend of nanowire growth discussed earlier. When the substrate is heated above room temperature, bismuth atoms on the substrate have surplus kinetic energy and can diffuse further, which allows a wider area of deposited bismuth to contribute to the nanowire growth, yielding thicker and longer nanowires with lowered packing density. When the substrate is cooled, however, bismuth filled into the trenches may become frozen and unable to be expelled for the lack of mobility. Eventually, the trenches are completely filled and subsequent deposition of bismuth results in a continuous film.

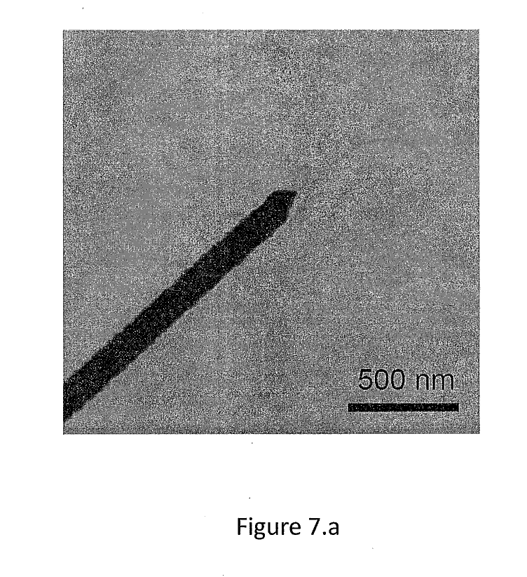

A demonstration for the present growth mechanism can be realized by high resolution in situ SEM studies, in which a subtle local heating induced by electron beam promotes bismuth nanowire growth from as-deposited vanadium/bismuth thin films. In FIG. 6 a sequence (6.a through 6.f) of SEM images taken from a same area on the film during continuous scanning is shown at 350 kX magnification, with 5 kV acceleration voltage and 86 pA beam current. The chosen scanned area is located between pre-existing bismuth nanowires, thus featuring a grainy thin film at the beginning. In a few seconds of scanning a bright particle erupts from a random location in the scanned area and appears to grow continuously into a nanowire. Later in the sequence, nanowires erupt from multiple locations in this area as can be seen in a real time SEM motion picture covering the in situ bismuth nanowire growth. The nanowires formed in this way are thinner (10-20 nm in diameter) than the ones formed during bismuth deposition, which reflects that the nanowire formation may be fed by a limited supply of residual bismuth trapped between vanadium islands/columns and that the small area under electron beam scanning may contribute to the growth.

### EXAMPLES

### Example 1

In this example, a forest of out-of-plane nanowires, grow over an entire area of the substrate. The nanowires have smooth surfaces with diameters of 90-120 nm and lengths of 6-8 μm. High resolution TEM and STEM images are respectively taken by a JEOL 2100F transmission electron microscope and a Hitachi HD2700C scanning transmission electron microscope. The specimen for elemental mapping is a 40-nm-thick cross-sectional slice of the bismuth/vanadium film mounted on a copper grid using the focused ion beam milling and lift-out technique. The EDX mappings and HAADF images are collected by a JEOL JEM-ARM200F atomic resolution analytical electron microscope.

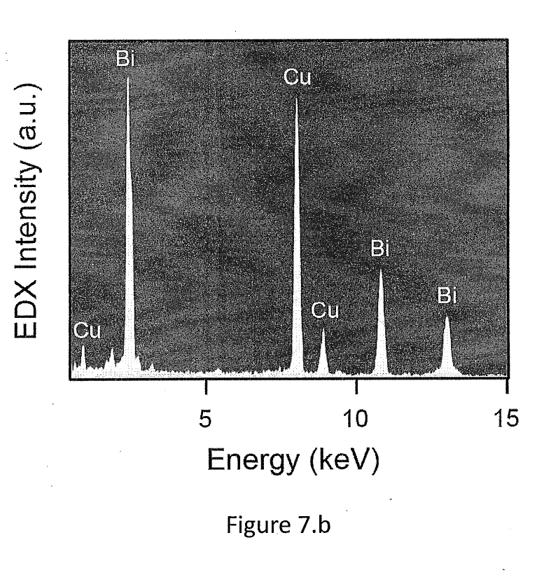

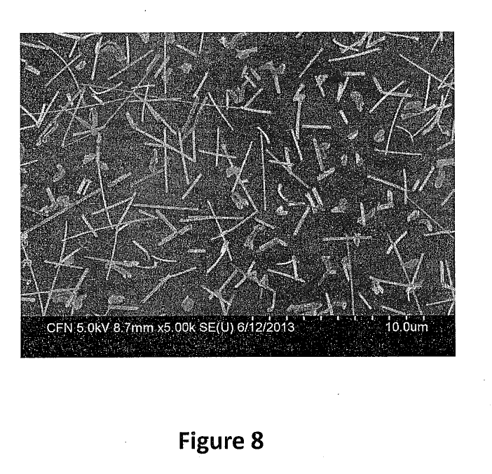

Scanning electron microscopy (SEM) study on the as-deposited thin films shows that a forest of out-of-plane nanowires, rather than a flat film, grows over the entire substrate (FIG. 1.b). Energy-dispersive X-ray spectroscopy (EDX) confirms that the nanowires are pure bismuth without alloying with vanadium (FIG. 7). It is estimated that over 70% of the bismuth deposited on the substrate is converted to nanowires (FIG. 8).

The deposited porous film is a matte grayish color rather than being mirror-like, as may be expected for thermal evaporation of metal. An X-ray diffraction (XRD) pattern recorded from the as-deposited sample (FIG. 1.c) shows sharp peaks corresponding to rhombohedral bismuth, suggesting large crystal domains. The absence of diffraction peaks from vanadium, however, may be due to its smaller grain size that gives substantial peak broadening. No other phases are observed, as bismuth and vanadium do not form solid solutions.

### Example 2

### Energy Dispersive X-Ray (EDX) Spectrum of the Nanowire

An EDX spectrum is collected in a JEOL 2100F TEM at 200 kV acceleration voltage. The sample is prepared by transferring as-grown nanowires to a carbon-film-coated copper grid using dry-transfer method. The TEM image of a typical nanowire and its EDX spectrum are shown in FIGS. 7.a and 7.b respectively. The EDX spectrum is indexed and shows a clear signal from bismuth but nothing for vanadium. The presence of a signal from copper is from the copper grid. It is therefore confirmed that the nanowires are purely bismuth.

### Example 3

### Yield of the Bismuth Nanowires

The yield of the nanowires may be defined as the ratio of the total volume of bismuth nanowires to the total volume of bismuth deposits on the substrate. For the experiment presented in FIG. 1.b, the bismuth deposits reach a nominal thickness of 50 nm, according to a calibrated quartz crystal thickness monitor. The nanowires have diameters of about 90-120 nm and lengths of about 6-8 μm. The packing density of nanowires is determined from top-view SEM images as ˜0.6 μm² (FIG. 8). Over an area of about 1 μm² the average total volume of bismuth nanowires is about 0.36 μm³, while the total volume of bismuth deposits is about 0.50 μm³. The apparent yield is about 72%.

### Example 4

### Heating of the Substrate by Bismuth Vapor

To achieve the 0.2 nm/s deposition rate at the substrate, the bismuth source is heated to 1006±2 K, which is determined by a type-K thermocouple in direct contact with molten bismuth. The heating source has a diameter of 1 cm and is 50 cm away from the substrate. The substrate is heated both by the source radiation and by the hot vapor. By assuming the source as a blackbody, the radiation power at the source surface is considered to be 5.81×10⁴ W·m⁻² through the Stefan-Boltzmann law. At the substrate the radiation power becomes 23.2 W·m⁻² following the R⁻² relation. The deposition rate of about 0.2 nm·s⁻¹ translates to the deposition of 9.4 μmol Bi per square meter per second. Using the thermodynamic constants of Bi listed in Table 1, it is estimated that when the Bi vapor condenses over the substrate and cools to 298 K, a heating power of 1.7 W·m⁻² is released. Altogether, the heat received by the substrate is found to be about 25 W·m⁻², or equivalently 2.5 mW·cm⁻². The power is not strong enough to lead to a significant temperature difference between the substrate and the substrate holder, which serves as a heat bath. In case of a 1-mm ITO (indium tin oxide) glass slide being used as a deposition substrate (thermal conductance ˜1 W·m⁻¹K⁻¹), at steady state, the temperature difference between its top and bottom surfaces is about 25 mK.

TABLE 1
Thermodynamic constants of Bismuth

| | |
|---|---|
| Heat of vaporization³³ | 151 kJ · mol⁻¹ |
| Heat of fusion³³ | 11.1 kJ · mol⁻¹ |
| Molar Heat capacity (liquid, 545 K)³⁴ | 30.4 J · mol⁻¹K⁻¹ |
| Molar Heat capacity (solid, 298 K)³³ | 25.5 J · mol⁻¹K⁻¹ |

### Example 5

### Keissig Fringe in the X-Ray Reflectivity from Vanadium Film

The X-ray reflectivity data shown in FIG. 3.c displays Kiessig fringe that arises from the interference between reflection beams from the top and bottom surface of the vanadium film. At large incident angle Q_{c} i.e., Q>>Q_{c} the film thickness D can be conveniently estimated by the relation D≈22π/ΔQ_{c} where ΔQ is the fringe periodicity. However, in the present case the Keissig fringe is only observed at smaller Q, as the film roughness damps the fringe at larger incident angle. Thus, in the following section is a discussion of how the film thickness may be interpreted from the Kiessig fringe.

As illustrated in FIG. 11, X-ray beams reflected from the top and bottom surfaces of a thin film have different optical path lengths, which may lead to constructive and destructive interference at different incident angles, thus resulting in the Keissig fringe. The film has a thickness of D and refractive index n₂ whereas the top medium has refractive index n₁, and the substrate has a refractive index of n3. The incident angle of X-ray is θ₁. The optical path difference thus writes ΔL=2D sin θ₂, where D is the film thickness and θ₂ is the angle of refraction that is given by Snell's law n₂ cos θ₂=n₁ cos θ₁. The phase difference between the two beams is φ=2πn₂ΔL/λ=4πn₂D sin θ₂/λ, where λ is the X-ray wavelength in vacuum. Therefore, between two neighboring reflectivity maxima (or minima) that are associated with incident angles θ₁ and θ₁′, thus refraction angles θ₂ and θ₂′, the following relation is established

4πn₂D sin θ₂′/λ−4πn₂D sin θ₂/λ=2π, Eq. #4

which explicitly gives the value of D through a simple reconfiguration:

D=λ/2n₂(sin θ₂′−sin θ₂), Eq. #5

From the equations above it is also apparent that the Keissig fringe will be evenly spaced when plotted against n₂ sin θ₂.

When the X-ray absorption is neglected, the refractive index of the X-ray in a medium is expressed by n₂=1−rₑρₑλ²/2π, where rₑ=2.818×10⁻⁵ Å, the classical electron radius, ρₑ the electron density, and λ the X-ray wavelength. Given the 22% porosity of vanadium film, its electron density ρₑ is found as 1.27 Å⁻³. Using λ=1.5416 Å for the Cu—Kα X-rays, n₂=1-1.35×10⁻⁵ may be obtained. In FIG. 11, the X-ray reflectivity presented in FIG. 3.c is plotted against n₂ sin θ₂ and does show a uniform period of Δx=(1.85±0.05)×10⁻³ for each oscillation cycle. From Eq. 2 the vanadium film thickness is found to be about 42±1 nm, which is consistent to the SEM image.

### The Surface-to-Volume Ratio of Bi Incorporated in Vanadium Film

The surface-to-volume ratio of Bi incorporated in the vanadium film can be estimated by the trench width between the vanadium islands. As the trench width is about 1 nm (FIG. 3.b), the surface-to-volume ratio S/V is ˜2 nm⁻¹ by treating the infiltrated bismuth as a thin slab. However, due to the uncertainty in the measurement of the trench width, a better estimation can be obtained from the vanadium film's microscopic structural parameters. In FIG. 12, the columnar structure within the film is depicted as an array of hexagonal cylinders over the substrate that has a surface area S₀. The hexagonal cylinders are characterized by side width a, height (also the film thickness) L, and packing density N. Based on these dimensions the porosity P of the vanadium film may be written as

$$P = 1 - \frac{{V}_{cylinder}}{{V}_{total}} = 1 - \frac{3 \sqrt{3} {a}^{2} {LNS}_{0} \text{/} 2}{{LS}_{0}} = 1 - 3 \sqrt{3} {a}^{2} N \text{/} 2 , \qquad Eq . \#6$$

where Vₜₒₜₐₗ is the apparent volume of the thin film. As the porosity is determined experimentally as 22% and the density of vanadium cylinders is 1.5-1.6×10⁴ μm⁻², the side width a is found at 4.5-4.3 nm, which agrees well with the TEM image shown in FIG. 3.b. When the trenches between vanadium cylinders are completely filled with bismuth, the surface area of bismuth may be written as

S_{Bi}=6aLNS₀+2PS₀. Eq. #7

The surface-to-volume ratio thus may be written as

S_{Bi}/V_{Bi}=(6aLNS₀+2PS₀)/PVₜₒₜₐₗ=6aN/P+2/L, Eq. #8

from which we obtain S_{Bi}/V_{Bi} at 1.89-1.93 mm⁴ using the film thickness 40 nm.

In an embodiment, an array of out-of-plane, single crystalline bismuth nanowires may be formed spontaneously when elemental bismuth (via Bi vapor) is deposited over a freshly sputter-deposited support layer (vanadium thin film) under high vacuum. The nanowires may be formed in the absence of an apparent catalyst.

Unlike the traditional vapor-liquid-solid (VLS) mechanism, it is the nanoporous structure of the sputter-deposited support layer (vanadium thin film) that confines the size of permeated bismuth domains during its vapor deposition, which causes a large surface-to-volume ratio and subsequent melting point reduction, rendering the bismuth domains molten or partially molten at room temperature. The release of surface energy provides a force for the domains to diffuse and to erupt from the porous thin film to form nanowires. Due to the universality of higher surface energy for nanoparticles, the mechanism could be generally applicable for scalable growth of one-dimensional nanostructures of various other materials with moderate melting points, such as tin or lead (232° C. and 328° C., respectively).

Moderate melting temperatures or melting points are melting temperatures in the range of greater than about 100° C. to less than about 1000° C. and more usually in a range of greater than about 200° C. to less than about 500° C. Furthermore, the absence of a catalyst in this method renders nanowires that are substantially free of catalyst. When utilizing a method involving a catalyst, diffusion of catalyst atoms into the nanostructures, may occur. The present method is for the growth of nanostructures that may be of higher purity and better controlled properties.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A method of forming nanowires comprising a semimetal, the method comprising:
supplying a substrate having a first surface;
depositing a thin film onto the first surface of the substrate;
supplying, under vacuum, a vapor form of a semimetal onto the porous film; and
continuously supplying the vapor form until nanowires of the semimetal are formed.

2. The method of claim 1, wherein the depositing further comprises a porous film of vanadium.

3. The method of claim 1, further comprising maintaining the substrate at room temperature.

4. The method of claim 1, wherein the thin film is porous.

5. The method of claim 2, wherein the thin film is sputter-deposited onto the first surface of the substrate.

6. The method of claim 2, wherein the thin film further comprises a columnar structure.

7. The method of claim 6, wherein the thin film further comprises a columnar structure with crevices in between the columns.

8. The method of claim 1, wherein the semimetal has a moderate melting temperature.

9. The method of claim 8, wherein the semimetal is selected from the group consisting of tin, lead and bismuth.

10. The method of claim 1, wherein the substrate is glass or silicon.

11. The method of claim 1, wherein the nanowires form an array.

12. A nanowire array comprising, a substrate having a first surface, a porous thin film coating the first surface, and nanowires in an array extending orthogonally to porous thin film.
